(19) United States
(12) Patent Application Publication
(10) Pub. No.: US 2026/0122952 A1
(43) Pub. Date: Apr. 30, 2026

(54) GaN HEMT WITH REDUCED THRESHOLD SHIFTING

(71) Applicant: Efficient Power Conversion Corporation, El Segundo, CA (US)

(72) Inventors: Robert Strittmatter, Tujunga, CA (US); Jianjun Cao, Torrance, CA (US); Robert Beach, La Crescenta, CA (US); Victor Estrada, Los Angeles, CA (US); Muskan Sharma, Torrance, CA (US); Wen-Chia Liao, Torrance, CA (US); Massimo Grasso, Trivolzio (PV) (IT); Alexander Lidow, Topanga, CA (US)

(73) Assignee: Efficient Power Conversion Corporation, El Segundo, CA (US)

(21) Appl. No.: 19/375,541

(22) Filed: Oct. 31, 2025

Related U.S. Application Data
(60) Provisional application No. 63/714,462, filed on Oct. 31, 2024.

(51) Int. Cl. H10D 30/47; H10D 30/01; H10D 62/85; H10D 64/00

(52) U.S. Cl. CPC H10D 30/475; H10D 30/015; H10D 62/8503; H10D 64/111

(57) ABSTRACT

A gallium nitride (GaN) transistor is provided having a voltage threshold at which the transistor turns ON. The transistor has one or more control electrodes and a gate electrode disposed on a GaN material layer. A bias is applied to the control electrode(s) to prevent shifting of the transistor voltage threshold.

### CROSS-REFERENCE TO RELATED APPLICATION

This application claims the benefit of U.S. Provisional Application No. 63/714,462, filed Oct. 31, 2024, the disclosure of which is incorporated by reference herein in its entirety.

### BACKGROUND OF THE INVENTION

### 1. Field of the Invention

The present invention relates to the field of column III nitride transistors such as gallium nitride (GaN) transistors.

### 2. Description of the Related Art

Gallium nitride (GaN) semiconductor devices are increasingly desirable for power semiconductor devices because of their ability to carry large current and support high voltages.

Development of these devices has generally been aimed at high power/high frequency applications. Devices fabricated for these types of applications are based on general device structures that exhibit high electron mobility and are referred to variously as heterojunction field effect transistors (HFET), high electron mobility transistors (HEMT), or modulation doped field effect transistors (MODFET).

A GaN HEMT device includes a nitride semiconductor with at least two nitride layers.

Different materials formed on the semiconductor or on a buffer layer cause the layers to have different band gaps. The different material in the adjacent nitride layers also causes polarization, which contributes to a conductive two-dimensional electron gas (2DEG) region near the junction of the two layers, specifically in the layer with the narrower band gap.

The nitride layers that cause polarization typically include a barrier layer of AlGaN adjacent to a layer of GaN to include the 2DEG, which allows charge to flow through the device. This barrier layer may be doped or undoped. Because the 2DEG region exists under the gate at zero gate bias, nitride devices are inherently normally on, or depletion mode devices. If the 2DEG region is depleted, i.e. removed, below the gate at zero applied gate bias, the device is an enhancement mode device. Enhancement mode devices are normally off and are desirable because of the added safety they provide and because they are easier to control with simple, low-cost drive circuits. An enhancement mode device requires a positive bias applied at the gate in order to conduct current. Transistors have a voltage threshold (Vth), which is the minimum voltage needed to turn the transistor on and allow current to flow between the source and drain terminals.

FIG. 1 illustrates an enhancement mode GaN transistor disclosed in U.S. Pat. No. 8,890,168, the entire disclosure of which is incorporated herein by reference. The GaN device of FIG. 1 includes a silicon substrate 11, transition layers 12, undoped GaN buffer material 13, undoped AlGaN barrier layer 14, p-type GaN (p-GaN) gate material 15, gate metal 17, dielectric material 18, drain ohmic contact 19, and source ohmic contact 20.

One of the shortcomings of prior art enhancement mode GaN transistors such as shown in FIG. 1 is that, under either gate or drain bias stress, charge traps or de-traps in the gate sidewalls, causing the device threshold voltage (Vth) to shift. FIG. 2 shows a conventional GaN gate GaN HEMT device, showing electrons 5 that have become trapped on the sidewalls of the gate GaN material 15. As electrons enter and become trapped in the p-GaN gate material 15, the voltage threshold increases dynamically.

### SUMMARY OF THE INVENTION

For all of the above-noted reasons, it is desirable to have an enhancement mode GaN transistor in which the Vth is stable and does not change over time.

In accordance with these and other objectives, a gallium nitride (GaN) transistor is provided having a voltage threshold at which the transistor turns ON. The transistor has one or more control electrodes and a gate electrode disposed on a GaN material layer. A bias is applied to the control electrode(s) to control the transistor voltage threshold.

### BRIEF DESCRIPTION OF THE DRAWINGS

The features, objects, and advantages of the present invention will become more apparent from the detailed description set forth below when taken in conjunction with the drawings in which like reference characters identify correspondingly throughout and wherein:

FIG. 1 shows a typical GaN transistor.

FIG. 2 shows a cross-section of the gate of FIG. 1A, with electrons trapped in the gate material.

FIGS. 3A and 3B are cross-section views of a first embodiment of a transistor device in accordance with the disclosure having a center gate and two outer control contacts.

FIG. 4 is a cross-section view of another embodiment of a transistor device in accordance with the disclosure having a gate and an outer control contact.

FIG. 5 is a cross-section view of another embodiment of a transistor device in accordance with the disclosure having two outer control contacts.

FIGS. 6A and 6B show configurations of AND and OR gates, respectively, using devices with multiple or discontinuous metal contacts to a single contiguous GaN region.

FIGS. 7A, 7B, 7C, 7D, 7E, 7F, 7G, 7H illustrate a process of fabricating a GaN HEMT device in accordance with the embodiment of FIG. 3B.

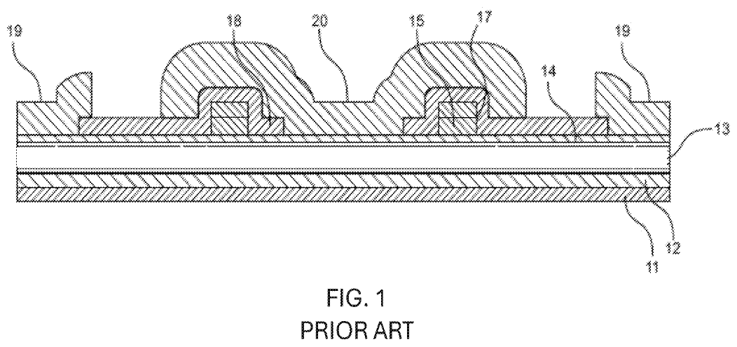

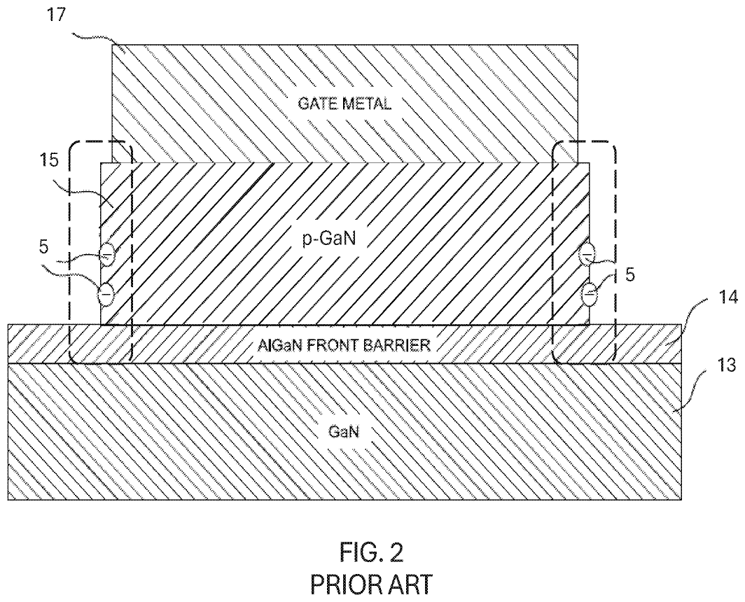

### DETAILED DESCRIPTION OF THE EMBODIMENTS

In the following detailed description, reference is made to certain embodiments. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings. It is to be understood that other embodiments may be employed and that various structural, logical, and electrical changes may be made.

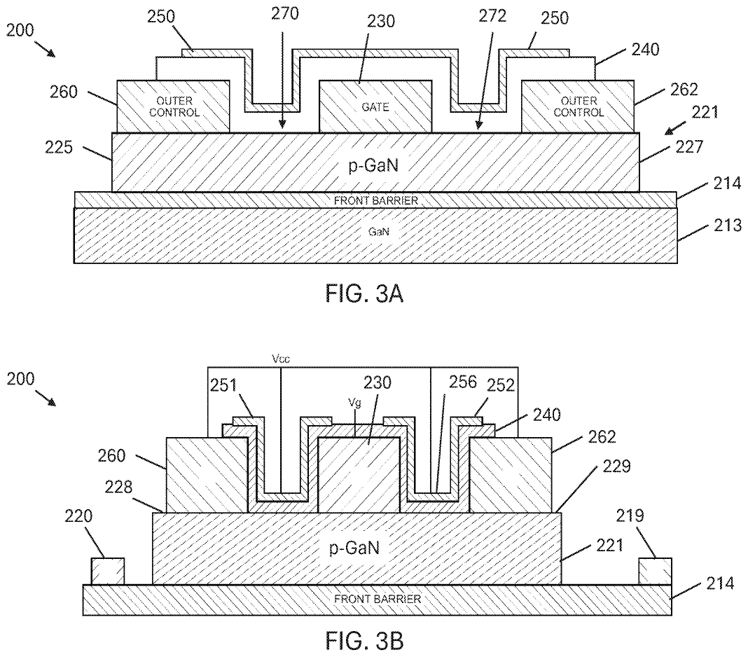

Referring first to FIGS. 3A and 3B, a GaN HEMT device 200 with reduced threshold shifting is shown in accordance with a first embodiment of the present disclosure. The GaN HEMT device 200 is illustrated having a buffer material layer 213 (undoped GaN) material; a front barrier layer 214 (AlGaN); a p-GaN material layer 221; and a gate electrode 230 formed centrally on the p-GaN layer 221. A source 220 and drain 219 are formed on the front barrier layer 214 on opposite sides of the p-GaN layer 221 and separated and electrically isolated from the p-GaN layer 221.

Outer control electrodes 260, 262 are directly disposed on and in direct contact with the p-GaN layer 221. The outer control electrodes 260, 262 are made of a conductive metal, such as TiN. In addition, the p-GaN layer 221 has a top surface 223, a first side edge 225 and a second side edge 227 opposite the first side edge. The first and second outer control electrodes 260, 262 are formed on the top surface 223 of the p-GaN layer 221 at the first and second outer side edges 225, 227, respectively, whereas the gate electrode 230 is at the middle of the p-GaN layer 221. The outer control electrodes 260, 262 extend along the side edges 223, 225, and are recessed inward from the side edges 225, 227 to form respective ledges 228, 229.

A gate electrode 230, and two outer control electrodes 260, 262 are provided. The outer control electrodes 260, 262 are separated and electrically isolated from each other and from the gate electrode 230, to form a first gap 270 and a second gap 272. The first gap 270 is between the first outer control 260 and the gate 230, and the second gap 272 is between the second outer control 262 and the gate 230. The outer control electrodes 260, 262 are on opposite sides of the gate 230, which is located between the outer control electrodes 260, 262. In addition, the first outer control electrode 260 has an outward-facing side that extends along the first side edge 225, and set inward from (or flush with) the first side edge 225 parallel thereto; and the second outer control electrode 262 has an outward-facing side that extends along the second material side edge 227, and set inward from (or flush with) the first material side edge 225 parallel thereto.

A thin metal layer 250 is optionally formed above the p-GaN layer 221 as either a single continuous gate metal (FIG. 3A) or partitioned into separate distinct metal layer sections (FIG. 3B). The metal layer 250 is directly disposed on and in direct contact with a dielectric layer 240 (preferably Si₃N₄). Metal layer 250 extends completely over the gate 230, at least partially over the outer control electrodes 260, 262, and, importantly, completely across the gaps 270, 272 between the contacts 230, 260, 262. The metal layer 250 is optional depending on the distance of the gaps 270, 272. For larger gaps, the metal layer 250 assists the gate to turn the device 200 ON by enhancing the 2DEG in regions beneath the gaps.

In FIG. 3A, the metal layer 240 is a single continuous layer. In FIG. 3B, the metal layer 240 is formed in segments 251, 252 extending only over the gaps 270, 272, and not completely over the gate.

In typical operation, the first and second outer control electrodes 260, 262, and the optional metal 250 (or optional metal segments 251, 252) are at a common potential Vcc, and biased so as to enhance the 2DEG in all regions under the p-GaN 221 except for immediately under the gate electrode 230. This positive potential Vcc is equal to the gate voltage at the ON state. When biased in this way, the device operates as a normal 3-terminal FET, with Source, Drain, and Gate terminals (4-terminal device with center gate acts as the Gate of a transistor, with the “outer control” plus the metal at DC bias, which equals the gate voltage at the ON state). However, advantageously, the transconductance action of the gate 230 is immune to charging (positive or negative) that may occur on the outer sidewalls of the GaN material layer due to charge trapping.

In operation, a positive voltage Vcc is continually applied to the outer control electrodes 260, 262, and a control voltage Vg is selectively applied to turn the gate 230 ON and OFF. The gate 230 controls the ON/OFF of the device 200. This is because the electric field from the optional metal layer 250 is screened by the metal of the gate 230, and thus does not reestablish the 2DEG, keeping the device OFF until a positive voltage is applied to the gate 230.

In accordance with the present invention, the positive voltage Vcc on the control electrodes 260, 262 advantageously removes the electrons trapped on the GaN material layer side walls 225, 227 and the ledges 228, 229. The control electrodes 260, 262 are placed at or nearby the material layer side walls 225, 227, so that the voltage Vcc can remove the electrons that are directly below the control electrodes 260, 262, as well as in the area surrounding the control electrodes 260, 262, which includes the p-GaN ledges 228, 229 and side walls 225, 227. The positive voltage Vcc on the control electrodes 260, 262 also reestablishes the 2DEG under the control electrodes (and under the gaps 270, 272, if the optional metal layer 250 is employed), such that the device is turned ON/OFF by the gate 230.

It is noted that in most power device applications, a low resistance between the drain 219 and source 220 is desirable when the device is turned ON, to lower the on-state voltage drop. In the present device 200, the RDS(on) is increased. However, an increased RDS(on) is acceptable for integrated-chip (IC) applications.

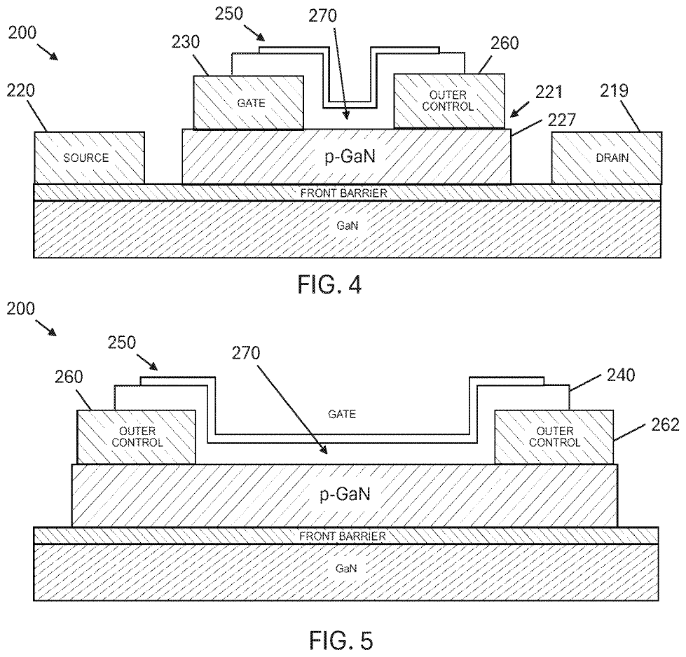

Turning now to the embodiment of FIG. 4, a gate metal 230 and a single outer control metal 260 is provided. The gate 230, control 260, gap 270, dielectric layer 240, and metal layer 250 are similar to the description above for FIGS. 3A, 3B, as to structure and operation. The outer control electrode 260 is located on the side of the GaN material layer 221 that is closest to the drain 219. The voltage threshold is typically dictated by the right side wall 227 on the drain side, since the drain 219 has a high positive voltage, and the electrons 5 are more likely to accumulate on the side of the GaN material layer 221 that is closest to the drain 219, i.e, on the side wall of the material layer 221. Accordingly, the positive voltage on the outer control 260 removes the electrons from the material layer 221 below the outer control 260 and at the nearby side wall of the material layer 221. In this embodiment, the outer control contact on the source side of the device (FIGS. 4, 5) has been removed. In FIGS. 3A, 3B, the voltage threshold Vth is immune to both gate and drain bias. However, in FIG. 4, the Vth is immune to drain bias only, as there is only an outer control 260 on the drain side. However, the saturation current and overall resistance-area product of FIG. 4 is improved compared to FIGS. 4, due to a narrower width. In addition, the embodiment of FIG. 4 can also be employed as a dual-gate FET, where both contacts 230, 260 to the p-GaN 221 are biased dynamically in circuit operation.

In FIG. 4, the saturation current (maximum current the device will let through) is set by the outer control 262 (e.g., 3V), e.g., using a DC signal with a large capacitor (which is a bit slow but exactly stops at the upper and lower voltages). The Gate 230 is then pulsed very quickly from 0 to 5 current, so the current moves quickly from 0 to 5. For example, in a LIDAR application, the amount of light for a close object can be very high, so less light is needed to avoid blinding the detector. But further objects need more light. Accordingly, the embodiment of FIG. 4 is able to rapidly switch to the appropriate level.

In the embodiment of FIG. 5, first and second control electrodes 260, 262 are provided, without a gate metal contact 230 (compare FIGS. 3A, 3B and 4). The control 260, gap 270, dielectric layer 240, and metal layer 250 are similar to the description above for FIGS. 3A, 3B, including as to structure and operation. Here, however, the metal layer 250 operates as the Gate of the device. If the gap between the first and second control electrodes 260, 262 is small, and a small negative Vth is applied to the metal 250 and the p-GaN is thin, the device can operate as a depletion mode FET. Whether enhancement mode or depletion mode, this embodiment has ultra-low gate leakage current, and the Vth is immune to sidewall charging on both sides (as in the FIG. 3A, 3B embodiment).

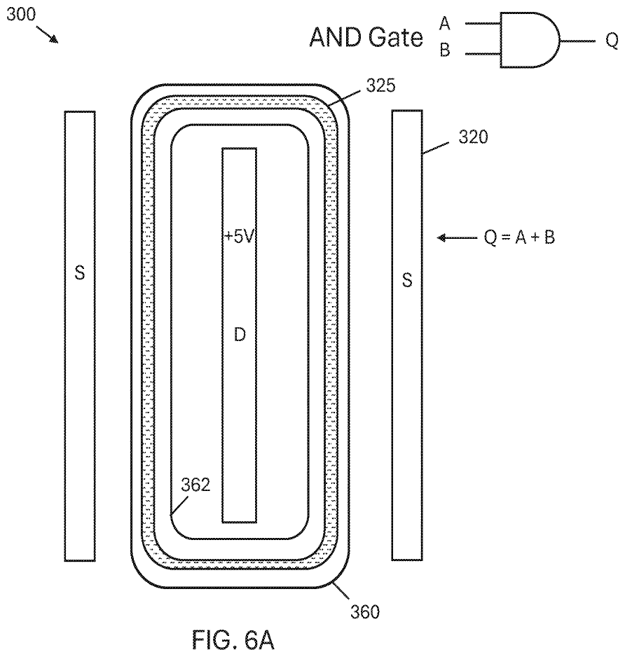

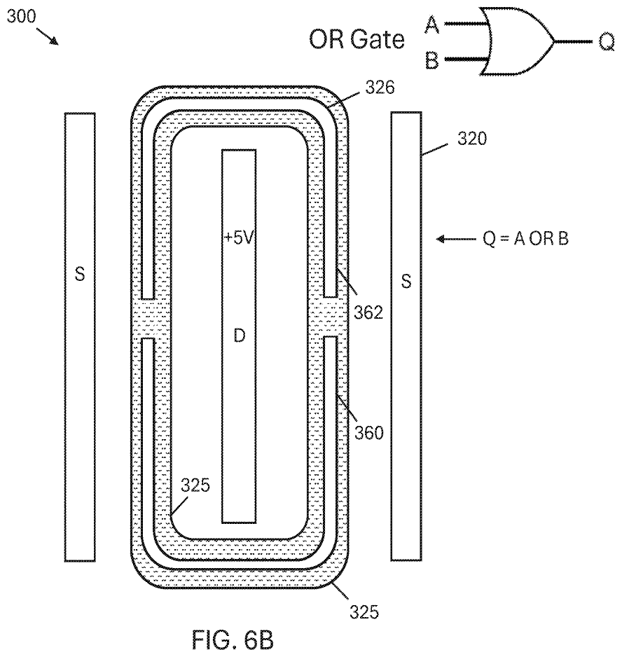

Turning now to FIGS. 6A, 6B, top views of embodiments are shown as examples of using the embodiment of FIG. 4 as a dual gate FET, where both contacts to the p-GaN are biased dynamically, to create basic logic gates, for example an AND gate (FIG. 6A) and an OR gate (FIG. 6B). FIG. 6A is a top-down view of an AND logic cell. The separate metal gate rings 360 and 362 share a common p-GaN island 325. For the cell to output a logic high Q on terminal 320 (the source), both metal gate rings 360 and 362 must be high. Otherwise, the output Q on terminal 320 is a logic low.

FIG. 8B is a top-down view of an OR logic cell. A single metal gate ring is broken into two separate horse-shoe shaped contacts 360 and 362. Both contacts 360 and 362 share a common p-GaN island 325. For the logic cell to output a logic high, either or both gate rings 360, 362 must be high. Otherwise, the logic output is low.

In summary, the device of the present invention has two or more metal contacts to a single contiguous p-GaN island, forming a novel GaN HEMT.

The first embodiment (FIGS. 3A, 3B) has three contacts to the p-GaN. The outer two metal contacts, in addition to an (optional) overlying metal, can be biased such that the resulting device operates as a normal three terminal FET. The FET is controlled by a gate contact between the two outer metal contacts. Because the gate is offset from the gate sidewalls, the threshold is not influenced by sidewall trapping. This results in a FET with a significantly lower VTH shift.

In the second embodiment, there are two contacts to the p-GaN, a metal contact on the drain side and a gate electrode. This design allows for a FET that is immune to VTH shifting induced by drain bias. It also allows for a dual-gate FET.

In the third embodiment, there are two metal contacts at the outer side of the p-GaN, and a metal plate overlaying the intervening central region. This embodiment allows for a depletion mode device with low (negative) VTH. It also allows for an insulating gate FET with ultra-low gate leakage.

In the fourth embodiment, multiple concentric or disconnected metal contacts to the p-GaN allow for basic logic elements.

All of the above-described embodiments of the invention can be combined with the hole injection and removal devices shown and described in U.S. patent application Ser. No. 19/301,309, filed Aug. 15, 2025, and U.S. Patent Application Publ. Nos. 2024/0274681 and 2025/0275216, the entire contents of which are herein incorporated by reference.

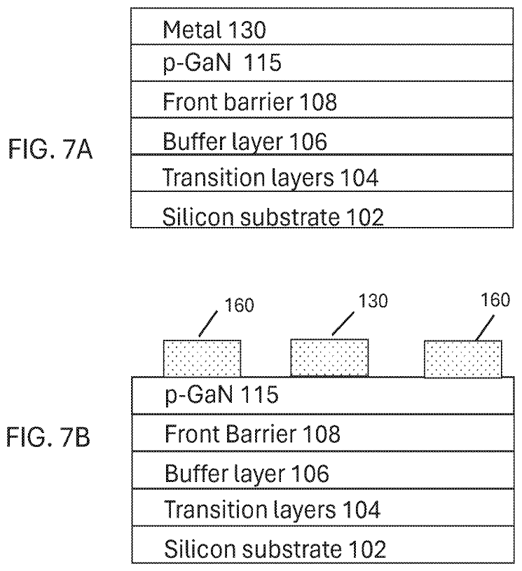

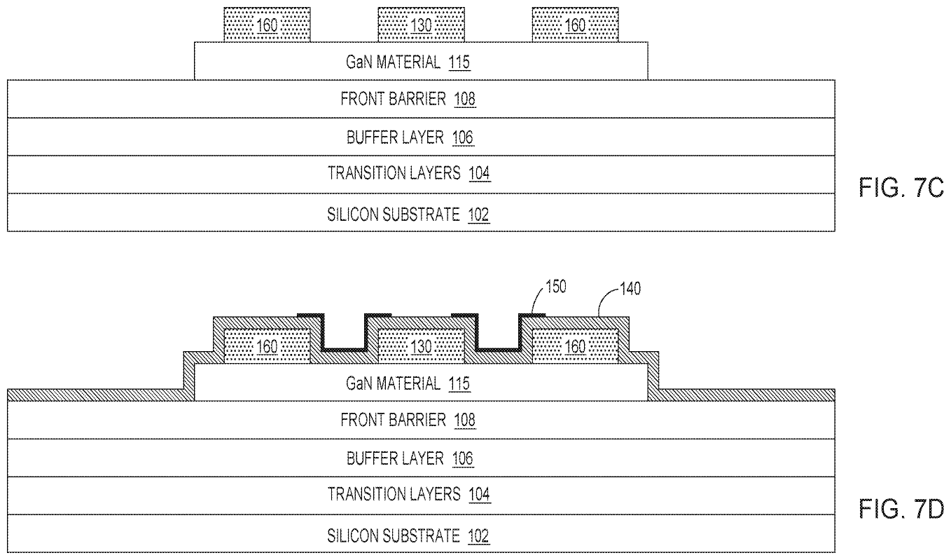

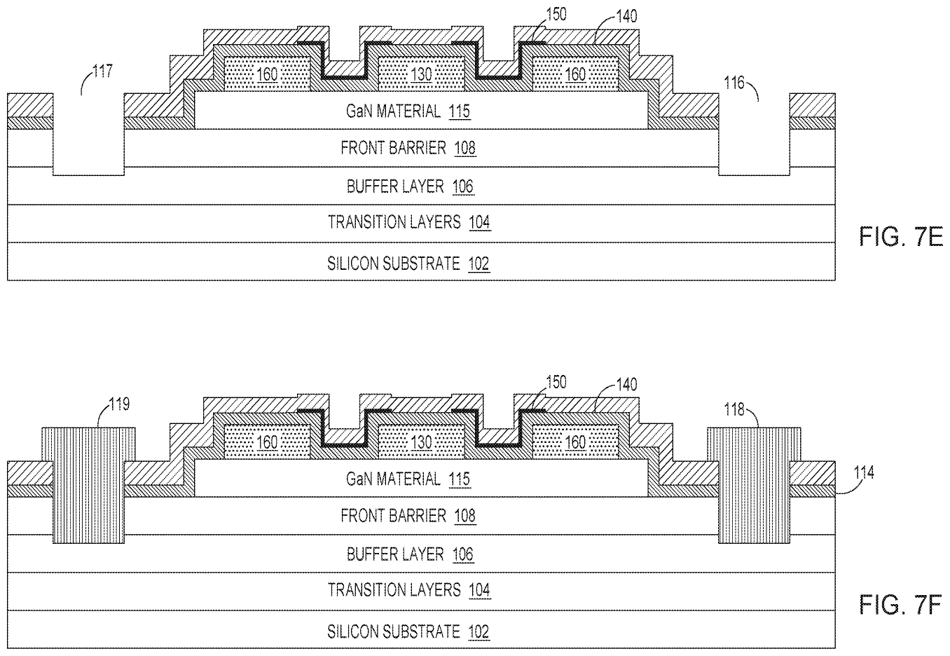

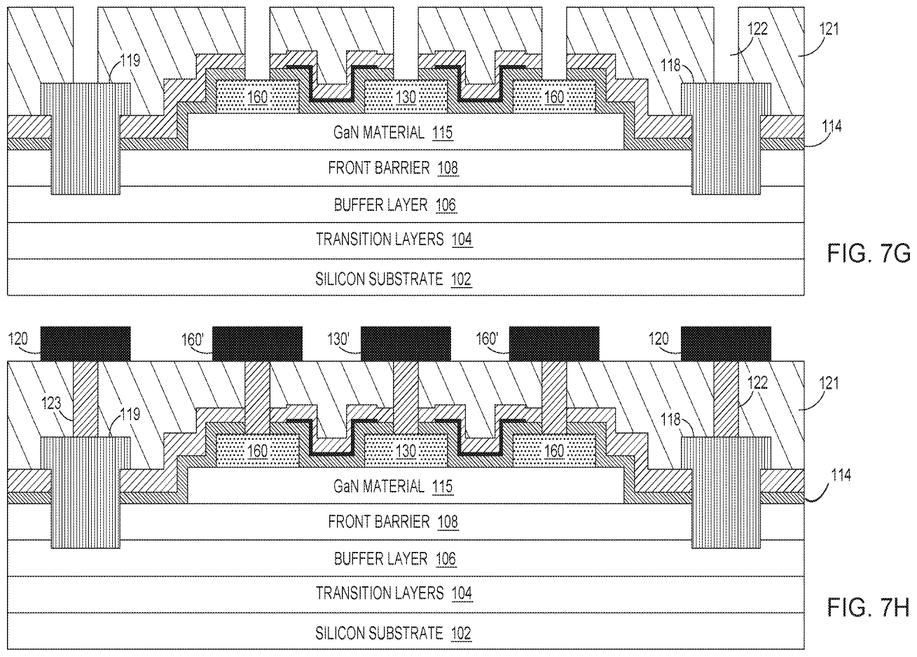

### Fabrication Process (FIGS. 7A-7G)

FIGS. 7A-7H illustrate a process of fabricating an enhancement mode GaN device in accordance with the embodiments herein. Similar to conventional formation of enhancement-mode GaN transistors, the description of the process begins from a structure (e.g., an epitaxial structure) that includes a silicon substrate 102, one or more transition layers 104 formed on the top surface of the substrate 102, a buffer layer 106 formed on the top surface of the transition layers 104, and an AlGaN front barrier layer 108 formed on the top surface of the buffer layer 106, for example, as disclosed in U.S. Pat. Nos. 8,890,168 and 10,622,455, the entire disclosures of which are incorporated herein by reference.

In accordance with the embodiments herein, as shown in FIG. 7A, the front barrier 108 has a barrier top surface. A p-GaN layer 115 is disposed (e.g., epitaxially disposed) on the barrier top surface of the barrier layer 108. A metal layer 130, such as titanium nitride (TiN), is deposited on the top surface of the p-GaN layer 115. The p-GaN layer 115 may be 20 nm to 120 nm thick.

In FIGS. 7B and 7C, the metal layer 130 is masked using a first mask and a portion of the metal layer 130 is etched to expose the p-GaN layer 115 and form the gate metal contact 130 and the outer contacts 160, for the embodiment of FIG. 3B, while maintaining the p-GaN layer 115. Rather than three contacts, two contacts can be formed, such as a single outer contact and a gate contact (FIG. 4), or two outer contacts and no gate metal contact (FIG. 5), and optionally one or more hole injector/collector contacts. Etching may be performed with a wet etch and may be performed by a process as described in U.S. Pat. No. 9,748,347, the entire disclosure of which is incorporated herein by reference.

In FIG. 7D, a first dielectric layer 140 is deposited over the gate metal 130 and the outer contact metals 160, and the gap therebetween. A metal 150 is then formed or deposited over the dielectric layer 140.

In FIG. 7E, a second dielectric layer is deposited over the device, including the gate metal 130, the outer contacts 160, the p-GaN layer 115, the barrier layer 108, the metal 150, and portions of the first dielectric layer 114. The dielectric layer may be deposited using Low-Pressure Chemical Vapor Deposition (LPCVD). The dielectric is preferably silicon nitride (Si₃N₄) with a thickness of ˜80 nm. The thickness of the dielectric layer may vary from 20 nm to 200 nm in accordance with embodiments. The deposition of the dielectric may further include annealing. For example, the ˜80 nm Si₃N₄ dielectric may be annealed at 850° C. The annealing temperature may vary from 750° C. to 950° C. for the Si₃N₄ dielectric.

After the deposition of the second dielectric layer, a mask may be applied and portions of the dielectric layers and the barrier layer 108 are etched to form a recess 116 for the drain contact and a recess 117 for the source contact to, into or through the front barrier 108 to or slightly into the buffer layer 106, as shown in FIG. 7E.

In FIG. 7F, an ohmic metal is deposited into the recesses 116 and 117 to form the drain first contact 118 and a first source contact 119, respectively, using a mask, further etching, and Rapid Thermal Annealing (RTA) at 550° C. The RTA temperature may be from 500° C. to 900° C.

In FIG. 7G, an Inter-Metal Dielectric (IMD) layer 121 is deposited over the device, namely over the top surfaces of the dielectric layer 114, drain contact 118, and source contact 119, as well as any exposed p-GaN material 115. The dielectric of the IMD 121 may be silicon dioxide (SiO₂). Following the IMD 121 deposition, the device is planarized to have a flat top surface. Contact vias 122 are etched through the IMD layer 121 to the drain contact 118 and the source contact 119 to form the source electrode 120, the drain electrode 124, the gate electrodes 130′ and outer control electrodes 160′.

In FIG. 7H, a tungsten (W) plug 123 is disposed in each of the contact vias 122 from FIG. 11F. Then, routing metal is disposed on each of the W plugs 123 to form connections to the source electrode and drain electrodes 120, the gate electrode 130′, and the outer control electrodes 160′ of the device. The contact vias couple the source electrode 120 to the source contact 119, the gate contact 130′ to the gate metals 130, the drain electrode 120 to the drain contact 118, and the outer control contacts 160′ to the outer control metals 160, respectively.

The above description and drawings are only to be considered illustrative of specific embodiments, which achieve the features and advantages described herein. Accordingly, the embodiments of the invention are not considered as being limited by the foregoing description and drawings.

More generally, even though the present disclosure and exemplary embodiments are described above with reference to the examples according to the accompanying drawings, it is to be understood that they are not restricted thereto. Rather, it is apparent to those skilled in the art that the disclosed embodiments can be modified in many ways without departing from the scope of the disclosure herein. Moreover, the terms and descriptions used herein are set forth by way of illustration only and are not meant as limitations. Those skilled in the art will recognize that many variations are possible within the spirit and scope of the disclosure as defined in the following claims, and their equivalents, in which all terms are to be understood in their broadest possible sense unless otherwise indicated.

1. An enhancement mode GaN HEMT transistor, comprising:
a p-GaN layer having a top surface, a first side edge, and a second side edge opposite the first side edge;
a first electrode disposed on the top surface of the p-GaN layer by the first side edge;
a second electrode disposed on the p-GaN layer by the second side edge; and
a gate electrode disposed on the p-GaN layer between the first electrode and the second electrode;
wherein, when a bias is applied to the first and second electrodes, the transistor operates as a field effect transistor controlled by the gate electrode.

2. The transistor of claim 1, wherein said p-GaN layer is a single continuous uninterrupted layer.

3. The transistor of claim 1, further comprising a metal layer overlaying gaps between the first and second electrodes and the gate electrode.

4. The transistor of claim 3, wherein the metal layer is continuous.

5. The transistor of claim 3, wherein the metal layer is discontinuous over the gate electrode.

6. The transistor of claim 3, wherein, when a bias is applied to the first electrode, the second electrode, and the metal layer, the transistor operates as a field effect transistor controlled by the gate electrode.

7. An GaN HEMT transistor having a voltage threshold at which the transistor turns ON, said transistor comprising:
a p-GaN layer having a first side edge and a second side edge, wherein the first side edge is on a side of the p-GaN layer closest to a drain electrode;
a first electrode disposed on the p-GaN layer by the first side edge, wherein, when a first bias is applied to the first electrode, charges accumulating at the side edge do not affect the voltage threshold of the transistor; and
a second electrode disposed on the p-GaN layer along the second side edge, wherein the second side edge is on a side of the p-GaN layer closest to a source electrode, wherein the transistor operates as a field effect transistor controlled by one or both of said first and second electrodes.

8. The transistor of claim 7, wherein the transistor comprises a dual-gate field effect transistor, wherein the first and second electrodes are both biased dynamically in circuit operation.

9. The transistor of claim 8, wherein the transistor is configured to operate as a logic gate.

10. The transistor of claim 7, further comprising a metal layer overlaying a gap between the first and second electrodes.

11. The transistor of claim 10, wherein the metal layer comprises a dynamically biased gate electrode and the first and second electrodes are biased such that charges accumulating along the first and second side edges do not affect the voltage threshold of the transistor.

12. The transistor claim 10, wherein a negative voltage is applied to the metal layer such that the transistor operates as a depletion mode transistor.
